(19) United States
(12) Patent Application Publication
(10) Pub. No.: US 2022/0221194 A1
(43) Pub. Date: Jul. 14, 2022

(54) "OFF" STATE MONITORING FOR CONSERVATION OVERRIDE APPARATUS AND METHOD

(71) Applicants: Gabriel Ayers, Bend, OR (US); Ryan Bello, Bend, OR (US)

(72) Inventors: Gabriel Ayers, Bend, OR (US); Ryan Bello, Bend, OR (US)

(21) Appl. No.: 17/576,908

(22) Filed: Jan. 14, 2022

Related U.S. Application Data
(60) Provisional application No. 63/137,713, filed on Jan. 14, 2021.

(51) Int. Cl. F24H 15/168; F24H 15/407; F24H 1/20

(52) U.S. Cl. CPC F24H 15/168; G01R 21/133; F24H 1/201; F24H 15/407

(57) ABSTRACT

A controller provides power to a water heater having upper and lower heating elements. Various options for measurement units to measure electrical parameters reflecting the state of the water heater are implemented to provide sensing of a desired parameter, whether the controller is powering the heating elements or not. A power relay is operably connected to power a testing or sensing circuit in one embodiment whenever the relay switches away from powering the water heater. In another embodiment, sensing circuits operate both during powered operation or non-powered condition for heating elements. Component damage and wear is greatly reduced, while also providing the controller an ability to assess the state of the heating elements, assure hot water, and override conservation methods like off-peak use, voluntary load shedding, and the like, in favor of guaranteed hot water output, based on measurements even in “power-off” conditions.

### RELATED APPLICATIONS

This application claims the benefit of U.S. Provisional Patent Application Ser. No. 63/137,713 filed on Jan. 14, 2021, which is hereby incorporated herein by reference in its entirety.

### BACKGROUND

### The Field of the Invention

This invention relates to optimizing timing of energy use in electrical devices, and, more particularly, to novel systems and methods for detecting and overriding the state of such devices, even when unpowered.

### The Background Art

Everyone is familiar with “rush hour” in traffic. Rush hour is legendary because such vast numbers of individuals in their vehicles, whether private or public transportation, are all on roadways and thoroughfares prior to and following a conventional work day. Surrounding these traffic rush hours is the peak demand time on utilities. For example, as families arise in the morning and prepare for work, school, or other daily activities, they will begin to use hot water, stoves, furnaces, and other utility-supplied appliances and equipment. Hot water in a modern home draws a large fraction, typically about half of the total energy use of a home. Accordingly, utilities, needing to supply energy in its various forms to households and businesses, implement demand schedules coordinated with pricing.

Industrial users, home users, and the like may obtain a better utility rate for either off-peak, or time-distributed (uniform; reduced maximum) demands for energy (e.g., gas or electricity). Shifting use to an “off-peak” time or otherwise modifying use can reduce, stabilize, or otherwise ease demands on distribution systems. Meanwhile, utilities may “load-shed” by denying power to certain users or devices in order to balance and limit power distribution.

Various systems have been developed to control the timing of draws or usage of electricity in various industrial and household processes. For example, in order to reduce overall use, many water heaters and furnaces are converted to “pulsed” operation. Such units, if fueled, have no pilot lights, but rather use a new ignition of a flame with every call for heat. If electric, they may likewise remain dormant until heat is called for. Likewise, water heater tanks have been shrunk, further insulated, or provided with mechanism to reduce power for hot water at peak times.

Current systems for monitoring, control, and delivery of heat energy require frequent switching of comparatively large electrical currents (full operational loads). Monitoring may be impossible when a heater is “off.” Also, precision of monitoring and control may be limited. It would be an advance in the art to provide a better, more accurate, more responsive, more durable, and more reliable system for detecting and controlling the state of a water heater. It would be an advance to monitor a heater even when it is off, in order to override conservation measures and avoid delivery undesirably cool water.

### SUMMARY OF THE INVENTION

In view of the foregoing, in accordance with the invention as embodied and broadly described herein, a method and apparatus are disclosed in one embodiment of the present invention as including a system relying on a controller for a water heater of a type having a lower and an upper heating element. These may be controlled by corresponding thermostats. Thermostats may be thermo-mechanical, meaning they mechanically respond to temperature in order to switch power to a heating element on or off.

In one embodiment, a controller includes a power relay connecting an alternating current (A/C) source of current through the relay to the water heater. The thermostats control electric energy to the heating elements. In one contemplated embodiment, a lower thermostat is set at a “set point,” with a “dead band” straddling it. The thermostat will control a switch to deliver current when its temperature drops below the lower bound of the dead band nominal set point. The thermostat will shut the switch off when its temperature exceeds a certain upper value above the nominal set point. The lower and upper values define a dead band wherein the heating element operates. Thus a set point is “nominal” for operation of and reference to a dead band.

The upper thermostat has its set point at a value lower than that of the lower thermostat. Thus, it will only engage when its temperature drops to its set point, because the lower heating element is not keeping up with demand and maintaining all water above the lower element at its set point. As a matter of thermal engineering, unobstructed free convection in an insulated tank of water operates comparatively rapidly. This means thermal (buoyant) rising and mixing is vigorous enough that all liquid above a source of heat will effectively have the same temperature for most practical purposes.

The switching effected by an upper thermostat may initially direct power to the lower thermostat and to operate within its own (lower) dead band unless and until it must in a cold water event (CWE), wrest control away. Thus, the upper thermostat takes control when it becomes too cool (arrives at its set point; bottom of its dead band) as the water temperature has already descended below the set point (bottom of dead band) of the lower thermostat. The lower thermostat is ceded control when the upper thermostat shuts down at a sufficient temperature and time evidencing that it is not needed to heat water.

Meanwhile, between the electrical grid and the water heater is a new controller. Here, consider the grid to include every connecting line from a source, such as a public utility, up through any connecting box and circuit breaker system and line servicing the venue or location of the end device (e.g., appliance; water heater). Herein, an appliance means a user of electrical power for heating. Typically it may include any water heater, hot tub, spa, pool, whirlpool, therapy pool, industrial heater of fluids (especially liquids), or the like. Whenever the term “water heater” is used, it is an example for any and all appliances.

The controller may include an electric parameter measurement unit (EPMU). The EPMU may either include or cooperate with a power monitor (PM). The EPMU may include an electrical measurement circuit (EMC). A power relay (PR) may connect in various ways to the incoming power line to measure electric parameters of upstream power and downstream loads. In some embodiments, the EPMU is activated only when power to the appliance has been switched off. In others, the EPMU may be active when power is connected. The EPMU may be connected and operable both when power to the appliance is connected and when it is disconnected.

The PR may include a double throw (DT) switch, and may be a single pole, double throw (SPDT) relay. In one embodiment, the EPMU may be powered and operable only when the PR disconnects a first pole powering the appliance to connect a second pole connecting the EPMU to the appliance. The EPMU may provide a comparatively small amount of power compared to operational (heating) power (approximately an order of magnitude less voltage, and multiple orders of magnitude less current).

In other embodiments, an EPMU, as a parallel circuit with respect to the PR. It can be testing (measuring) an electrical parameter in the circuit through the appliance while operational power runs from the PR to the appliance. Connected in parallel, it also operates when the operational level of power to the appliance is shut off by the PR.

In either type of mechanism, a trickle current enables sensors to detect a parameter (e.g., resistance, voltage, current, etc.) through the heating element tested. That parameter is processed to determine a state of the appliance, such as which heating unit is active, what the condition of the system is, and so forth. Thus, the processor can send a resulting instructional signal to the PR to change the state by switching power.

Herein, reference to a single pole double throw relay or SPDT, is one of the simplest ways to implement the invention. In fact in the parallel circuit EPMU embodiments, even a single pole single throw (SPST) relay, which electrically connects at only a single pole to be on an disconnects to be off, may be used as a PR. However, in some embodiments, it needs to be of the SPDT type. It switches from its normally closed pole on the A/C input (grid) side to the normally open pole on the EPMU side.

A distinct advantage to this connection scheme of an A/C source and EPMU, each connecting to a PR controlling the power feeding a water heater, permits an almost instantaneous check of a parameter like resistance, reflecting the state of the appliance. Thus, any time the control mechanisms (e.g., thermostats, etc.) of a water heater call for heat, or to shut off heat, the EPMU may provide an instantaneous reading of one or more electrical parameters. The EPM then continues to monitor (measure and report) the value of the parameter even when operational power to the appliance is shut off. This provides great benefits. The parameter may be processed by a processor to determine the state of the appliance. In one embodiment that parameter depends on and reflects a temperature of a heating element and which element is operating, and therefore the state of the appliance.

A temperature of inadequately heated water is detected by the upper thermostat. This indicates a need for higher temperature, to be met by switching from the lower heating element (unit) to the upper heating element. That element, thus engaged by itself, affects only the water above it. It applies its rated heat output thus into a smaller volume (about 20 to 50 percent of the tank, typically about a third). Thus the heat per gallon is increased, although only a smaller volume of heated water will be available. This rapid response may override other conservative measures in place, but spare a user receiving water at too low temperature.

Through all of this operation of the appliance, the controller need only determine what the state of the appliance is. Based on that state, the controller may respond by providing timely the power connection needed. The system dramatically reduces the number of times the PR needs to switch, similarly reduces the current and voltage across it needed to measure the parameter. These result in a much longer calendar lifetime for the PR as well as a significantly (orders of magnitude) faster response to a state change of the appliance. An apparatus and method in accordance with the invention may more precisely and quickly determine the current state and dictate appropriate action by the PR. Thus, energy efficiency (conservation methods) may be implemented, yet monitoring continues in the off” state. A user need not even be aware that the upper heating element has been engaged, heating a reduced volume of water (only that above it), more rapidly than the entire tank could respond, thereby preventing a cold shower or cold laundry.

### BRIEF DESCRIPTION OF THE DRAWINGS

The foregoing and other objects and features of the present invention will become more fully apparent from the following description and drawing. Understanding that this drawing depict only typical embodiments of the invention and is, therefore, not to be considered limiting of its scope, the invention will be described with additional specificity and detail through use of the accompanying drawing in which:

FIG. 1 is a schematic block diagram of one embodiment of a system in accordance with the invention wherein a controller provides operational power delivery to and testing (measurement) of an appliance (here a water heater as an example). A power relay (PR) connects a low-power, low voltage, low-current electrical parameter measurement unit (EPMU) to provide repeated and virtually instantaneous measurement. The electrical parameter reflects the state of the appliance. A process or the analysis parameter, determines the state of the appliance, and programmatically initiates a suitable, programmed response controlling the PR, thereby controlling the state;

FIG. 2 is a schematic block diagram of a system and process for balancing operational requirements of an appliance, such as a water heater or the like, to provide power-saving operation like load shedding desired by a utility, while still overriding it to avoid a cold water discharge by that appliance;

FIG. 3 is a schematic block diagram of a method for determining a state of appliance by monitoring an electrical parameter in a controller, in an appliance, or both in order to track certain electrical parameters, determine the state of the appliance, and, when appropriate, instruct a power relay to override other conservation requests or conditions, in order to power up an appliance to avoid a cold discharge;

FIG. 4 is a schematic block diagram of a method using a resistance measurement circuit (RMC) for monitoring an appliance, and controlling a power relay to balance the competing needs of power conservation and avoiding a cold water discharge event where the RMC detects an electrical parameter, even when the power relay is off, and especially when it is off;

FIG. 5 is a schematic block diagram of a process of monitoring the appliance continuously by a parallel capacitive dropper (CD) or triac “Dimmer” (TD) to determine the operational state of the appliance and determine whether to instruct a power relay to override a power-conserving condition to avoid a cold water discharge, and

FIG. 6 is a schematic chart representing a graph of a parameter measured by a CD or TD type EPMU.

### DETAILED DESCRIPTION OF THE PREFERRED EMBODIMENTS

It will be readily understood that the components of the present invention, as generally described and illustrated in the drawings herein, could be arranged and designed in a wide variety of different configurations. Thus, the following more detailed description of the embodiments of the system and method of the present invention, as represented in the drawings, is not intended to limit the scope of the invention, but is merely representative of various embodiments of the invention. The illustrated embodiments of the invention will be best understood by reference to the drawings, wherein like parts are designated by like numerals throughout.

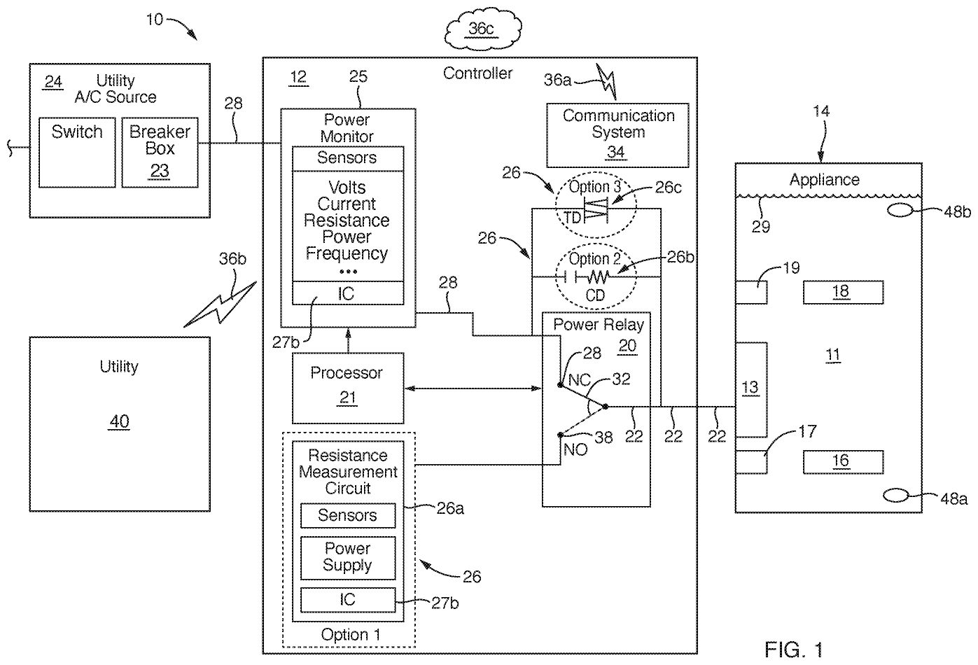

Referring to FIG. 1 and FIGS. 1 through 6 generally, a system 10 may be implemented in accordance with the invention to measure and control heating of liquid in a container 11 or tank 11. A system 10 may include just the controller 12, or may include the water heater 14, or even a source 24 of power. The controller 12 is responsible to control power to the appliance 14, such as a water heater 14. In this electronic age, a more complex native controller 13 may be built into a commercial water heater 14. On the other hand, a conventional “native controller” may reduce to simply a set of upper and lower heating elements 16, 18, activated in response to corresponding, thermomechanical thermostats 17, 19. In the figures, broken lines indicate optional devices and positions. Square brackets also represent non-required options.

For example, a water heater 14 may be defined by a wall 15, which may form a tank 11 inside an insulated region covered by an outer covering or the like. The specific construction is not important at this point, to the invention. Nevertheless, a wall 15 defines a volume 11. The volume 11 may be characterized as the contents 11, or the tank 11, and so forth. By whatever mechanism, the volume 11 contains water 11 that is heated by the water heater 14. The appliance 14 may have a liquid level 29 that leaves space above itself. In certain embodiments, the liquid level 29 will simply be the top of the tank 11 of the appliance 14.

In the illustrated embodiment, the water heater 14 includes a lower element 16 driven by electrical power to heat up, in turn heating up the contents 11, or the tank volume 11. A thermostat 17 is positioned just above the lower element 16. This is because water in a tank 11 will typically circulate in unobstructed, free convection comparatively rapidly. Any variation in temperature with height above the lower element 16 may range from a few degrees to as little as a fraction of a degree, depending on the insulation of the wall 15.

Similarly, an upper element 18 is also associated with an upper thermostat 19 placed just above the upper element 18. This serves the same purpose of similarly detecting the temperature above the upper element 18 at any time. The lower thermostat 17 operates based on a higher “set point” temperature than does the upper thermostat 19. The upper element 18 is not powered unless its temperature is below its own set point, which is below the set point temperature of the lower thermostat 17. The upper thermostat 19 diverts a power to the lower thermostat unless and until it itself is triggered on.

In the controller 12, a power relay 20 (PR 20) operates to turn on or shut off power to the appliance 14. One or more processors 21 may be responsible to process data incoming and outgoing, between an optional power monitor 25, an EPMU 26, the PM 25, and the PR 20. It 21 may, but need not, communicate across a digital internetwork 36c, such as the Internet 36c. The relay 20 controls power delivered to an output line 22 (circuit 22), selectively connecting the appliance 14 to, and disconnecting it from, a current source 24, typically an alternating current (A/C) source 24.

The power monitor 25 may be responsible for power delivery to the appliance 14 when on. It may measure current, voltage, frequency, and any other electrical parameter of interest corresponding to power from the source 24 through the line 22 to the appliance 14. For example, it may be configured to be part of an EPMU 26 when operated with the CD 26b or TD 26c in certain embodiments. For example operating a measurement device 25 in conjunction with a capacitive dropper 26b (CD 26b) or triac dimmer 26c (TD 26c), constitutes an EPMU 26 using a parallel circuit detection scheme, as explained hereinbelow. Meanwhile, the EPMU 26 connects to the relay 20 in one of multiple optional arrangements, including serial and parallel connections. Various integrated circuits 27a, 27b, and network connections may also be in components within the system 10.

In general, a system 10 may be thought of as including a controller 12, or the controller 12 may itself be considered a system 10 to be installed between a power source 24 and an appliance 14. In another sense, one may think of a system 10 and method 60, 100, 110, 120 as including all three 12, 14, 24. Nevertheless, the system 12 or controller 12 provides a significant benefit in reliability of the PR 20, its operational response time, lifetime, and more. Moreover, it responds to a cold water event (CWE), a condition when the upper thermostat 19 is triggered on to ameliorate a risk or of sub-temperature (too cold) water delivered by the appliance.

For simplification of control, only a single element 16, 18 is operational (powered) at any given time. Recall that the tank 11 is at virtually a single temperature above an active heating element 16, 18. This is a direct result of substantially unobstructed free convection as hot plumes of liquid rise from a heating element 16, 18 to the top liquid level 29. Ultimately, free convection results in fluid repeatedly cycling up to the surface, back down to the heating element, and mixing to equalize temperature throughout. Thus only the lower heating element 16 need operate, so long as it can deliver water (liquid) at a temperature corresponding to the set point of its thermostat 17.

However, what happens if demand (outflow) from an outlet 48b is too great? What if load shedding turned the appliance off? What happens when the lower element 16 does not keep temperature in the tank at the nominal set point of the lower thermostat? Eventually the temperature may fall. When it does, and if it continues, eventually the temperature at the upper thermostat 19 will drop below its own set point. This triggers the upper thermostat to take the incoming power and switch it to go through the upper thermostat 19 and heating element 18.

Due to free convection (buoyancy of a heated water plume in a tank 11 at a lower temperature), the upper heating element 18 does not heat any liquid below itself. A temperature profile will reflect a lowest temperature below any active heating element 16, 18, a steep gradient (temperature rise as a function of distance upward) along the vertical extent of that active element 16, 18, followed eventually by a virtually constant temperature above the active element 16, 18.

Therefore, once the upper thermostat 19 switches power to the upper heating element 18, or heating unit 18, temperature below it cannot rise. Only liquid within the vertical extent of the unit 18 can rise in temperature, sending a vertical plume upward from the unit 18, and heating the liquid above the heating unit 18 to a temperature. This alleviates the cold water event more quickly than the lower heating unit 16 could have, for two reasons. First, less water (liquid) lies above the upper heating unit 18. Second, the upper unit 18 should have the same construction as the lower unit 16, and thus the same heating capacity (energy output per unit time). Therefore the same rate of heat transfer into a smaller volume and mass of liquid results in a faster temperature rise of that liquid. The liquid below is not heated, as hot, buoyant plumes in a fluid only rise.

All processes take time. So, one is left with the problem of how to detect the state 89 of the appliance 14 (e.g., water heater 14), and how to respond with appropriate power from the power source 24 through the controller 12. The appliance 14 has several distinct states 89 and corresponding transitions therebetween. The controller 12 needs structural and operational mechanisms to effectively measure a parameter in the appliance 12 that reflects the state 89 thereof. It needs some scheme to process that parameter to identify the state 89. It then needs a method to use that identification of the state 89 to control delivery of power from the source 24 to the appliance 14, and hardware in the controller 12 to do so.

In one embodiment of a controller 12, a power relay 20 (PR 20) may operate. It may be of a single pole single throw (SPST) type if the EPMU 26 connects like the EMC 26a in parallel with the PR 20. It relies on a double throw (DT), needing only a single pole, double throw (SPDT) if the EPMU 26 is connected in series to the PR 20. In such a case, the PR 20 includes a pole 28 normally closed (NC) and a pole 30 that is normally open (NO). In the illustrated embodiment, a switch 32 is normally closed with the pole 28, carrying power from a power source 24 through the controller 12 to the device 14.

A native controller 13 may be an electronic device 13, but need not be. It may typically be the simple switching mechanisms of two thermomechanical thermostats 17, 19 operating to switch power to their corresponding heating units 16, 18 as described hereinabove. Native simply means it 13 is provided from a manufacturer with the manufactured appliance 14.

An optional, communication device 34 in the controller 12 may be connected through a series of links 36a, 36b, 36c to a communication device 38 at a utility 40. It permits some additional functionality but is not necessary. Collecting and communicating data are helpful for receiving information from a utility or another requesting load shedding. They can help with certain aspects of the invention, but are not necessary.

For example, a utility 40 may have policies, protocols, controls, agreements, and the like providing for power shutdowns at times in order to “load-shed” to balance line loads, remove unnecessary peak power delivery, reduce customer costs, and so forth. A utility 40 may want to communicate through a communication device 38a, based on inputs and outputs to a processor 38b relying on a data collection device 38c. Various data that may collected in a database 38d. A communications device 34 in the controller 12 may connect by a series of links 36a, 36b, 36c, but such is not required for satisfactory operation of the controller 12.

Referring to FIG. 1, and FIG. 1 through generally, a water heater 14 or other appliance 14 having multiple heating units 16, 18 may benefit from a controller 12 electrically connected to control power to, and detect the state 89 of, the water heater 14. A significance of this connection scheme is that the controller 12 may be installed on the utility side (e.g., power grid side; breaker box side, etc.) rather than requiring modifications of a water heater 14 itself (the appliance 14 side of the power circuit). Operation of a system 10 in accordance with the invention does not require a modification of any appliance 14.

In the illustrated embodiments, the controller 12 may include a PR 20 feeding A/C power to an output line 22 (circuit) powering the appliance 14. The PR 20, being a single pole, double throw (SPDT) type is normally closed when connected to the A/C source 24 through a switch box 23, circuit breaker 23, or the like 23. The PR has a first pole 28 normally closed (NC) by the switch 32, connecting power to feed the line 22. Thus a normally closed (NC) position feeds alternating current through the pole 28 to the switch element 32 feeding the line 22 powering the appliance 14. The line 22 and appliance 14 constitute a circuit as in standard electrical schematics.

Whenever the PR 20 opens the switch 32, it 32 moves to the opposite, normally open (NO), pole 30. In a first option, the switch 32 on the pole 30 connects the line 22 to the resistance measurement circuit 26a (RMC 26a) as an EPMU 26. In a second option, the PR 20 may be the same or a single throw (ST) relay 20, with a capacitive dropper 26b (CD 26b) circuit connected in parallel with the PR 20. Opening the PR 20 shuts off power through the switch 32, but not through the CD 26b. In a third option, when the PR 20, acting as an ST relay 20, is opened, it shuts off power through the switch 32 but not through a parallel triac dimmer circuit 26c (TD 26c). The last two options may rely on the power monitor 25 (PM 25) to measure electrical parameters reflecting current, voltage, resistance, etc. through them. These three foregoing options are all shown, but are mutually exclusive. Thus, in FIG. 1, only one of the circuits 26a, 26b, 26b would exist in the controller 12.

Whichever EPMU 26 is used, it provides only a comparative trickle of current (orders of magnitude less than operational current required to heat a heating unit 16, 18). An EPMU may use modest current (e.g., milliamps vs. 20-40 amp heating) at a modest voltage. Voltage is typically an order of magnitude less than that required to operate the heating units 16, 18 (e.g., 3 to 15 volts, rather than 110 to 220 volts). The RMC 26a also measures from its own power provided to the appliance 14 through the line 22 any electrical parameters of interest (e.g., current, voltage, resistance, power, etc. through it to the appliance 14), typically resistance. In this embodiment, the PM 25 is useful for other monitoring, but not necessary to the operation of the RMC 26a as an EPMU 26a.

In the second option, the CD 26b is connected in parallel with the switch 32 when closed and powering the appliance. Its electrical parameters (e.g., current, voltage, resistance, power, etc. through it to the appliance 14) may be measured by the PM 25. Similarly, the third option relies on a PM 25 to measure any selected electrical parameter through the TD 26c circuit connected in parallel with the PR 20. Thus, a trickle of current passes through the TD 26 whether the switch 32 is open or closed, and the PM 25 may measure that or other parameters.

The controller 12 permits power-shedding. Otherwise, the PR 20 would have to be toggled multiple times in order to continue to monitor. If a PR 20 is good for operation for one hundred thousand cycles, and every power-shedding event is causing five, ten, or a hundred switches, the life of the relay is greatly shortened. With the controller 12 and its RMC 26a in place, the relay 20 only needs to switch when power is to be shut off, according to conservation on requests from the utility 40 or the controller 12

The measurement taken by an EPMU 26 in any configuration is used to identify the state 89 of the appliance 14. In the context of saving energy, the tank 11 may be maintained at temperature by the lower heating unit 16 during low-demand or off-peak times. During power shedding it may be off. However, once a large draw of water is taken from the outlet 48b, the water may cool. The lower thermostat 17 powers the lower heating unit 16 only when on, and only in response to the temperature drop caused by relatively “cold” incoming liquid through the inlet 48a. Conventionally, a bi-metallic, thermomechanical thermostat 17 responds to water temperature directly, but slowly. Temperature detection takes seconds, but temperature change takes minutes. A controller 12 in accordance with the invention responds much more quickly and accurately to the state of the heaters 16, 18, not the water. The EPMU 26 requires minimum number of actuations and current draw through the PR 20 to take the necessary measurements in any configuration of EPMU 26.

The state 89 of the appliance 14 in the example includes conditions of on (powered), and off (unpowered), with the latter including a “top” mode (top heat) in which the top heating unit 18 is powered, and a “bottom” mode (bottom heat) in which only the bottom heating unit 16 is powered. The two conditions, one with two modes, constitute three states 89 of the water heater 14. The water heater 14 itself, in this example, is one that entirely controls itself. If line 22 delivers power to the appliance 14, the appliance operates under the control of its two thermostats, as described hereinabove.

The transitions between states 89 typically include “off to bottom on,” because temperature of a lower thermostat 17 is above its dead band temperature (defined between Tₘₐₓ/off above a nominal set point temperature and Tₘᵢₙ/on below that set point). When hot water is released through an outlet 48b from the tank, the lower thermostat 17 soon experiences cold incoming water from the inlet 48a. When temperature in the thermostat drops below the dead band, it directs power to the lower heating unit 16.

The power relay 20 may be embodied in one of several configurations. Two of the currently contemplated embodiments include a single pole double throw type in which the switch 32 moves between a pole 28 that is normally closed to a pole 30 that is normally open. When the switch 32 moves away from the pole 28, power between the utility source 24 and the appliance 14 is completely shut off. This kind of event may be precipitated by a request for reduction or usage. Such a request may come through a communication device 34 and the controller 12 receiving a communication from a utility 40 through its communication system 38a and the links 36a, 36b, 36c. A utility may declare or request a load shedding event by a user. Accordingly, the controller 12 having received through the communication device 34 such an instructional request. It may instruct the processor 21 to open the power relay 20. In this event, the power relay is still under the controller 12, and may be closed back to the pole 28 by the controller 12 because of some overriding reason.

One overriding reason is if the appliance 14 is at risk of delivering through its outlet 48b too cold water. It may be on or off, but is monitored and determined to be close to such a cold water delivery. The processor 21, after proper monitoring and decision making, may instruct the power relay 20 to close the switch 32 against the pole 28.

On the other hand, a controller 12 or processor 12 may have programming based on a calendar. For example, every processor 21 has a clock and that clock may be used to feed information to a calendar specifying times of day when the power relay 20 should be closed and other times that it should be opened, against the pole 30. For example, a utility will typically offer better power rates for off-peak use. Accordingly, a user of an appliance 14 may set a controller 12 to restrict access by the appliance 14 to power during certain hours. Likewise, a processor 21 may receive information from either a utility 40, an owner of an appliance 14, or from some algorithm in the processor 21 itself to determine that the power relay 20 should be opened (off). Closed, in the normally closed position, is the switch 32 being closed against the pole 28. Open means that the switch 32 has opened the power circuit between the appliance 14, PM 25 and utility source 24.

FIG. 1 includes three alternative embodiments for circuits enabling sensing (monitoring, measuring) of condition or the sensing a parameter that will reflect the condition 89 (state 89) of the appliance 14. These are not used together. There is no need to use two of them. However, any of these alternate circuits might be used in order to detect a parameter, detect a value thereof, and provide that parameter to the processor 21. In the illustrated embodiment, the RMC 26a will connect to the apparatus 14 or appliance 14 whenever the switch 32 is in the normally open position on the pole 30. The processor may then use the value to determine the state 89 of the appliance 14. It may then programmatically provide instructions to the power relay 20.

On the other hand, either the capacitive dropper 26b or the triac dimmer 26c may connect in parallel with the PR 20. Either may monitor the appliance 14 (electrical parameters associated therewith). Both operate while the PR 20 is closed or open. Either of those circuits 26b, 26c may connect in parallel to the power relay 20 and switch 32. Meanwhile, when the power relay 20 is in the open position, each of the sensor circuits 26b, 26c is still connected but permitting very little power to flow to the appliance 14, only enough to continue producing a signal to be monitored by the PM 25.

In the alternative, the resistance measurement circuit 26a or RMC 26a operates when the PR 20 with a double throw switch 32 is disconnected from power, in the normally open position 30.

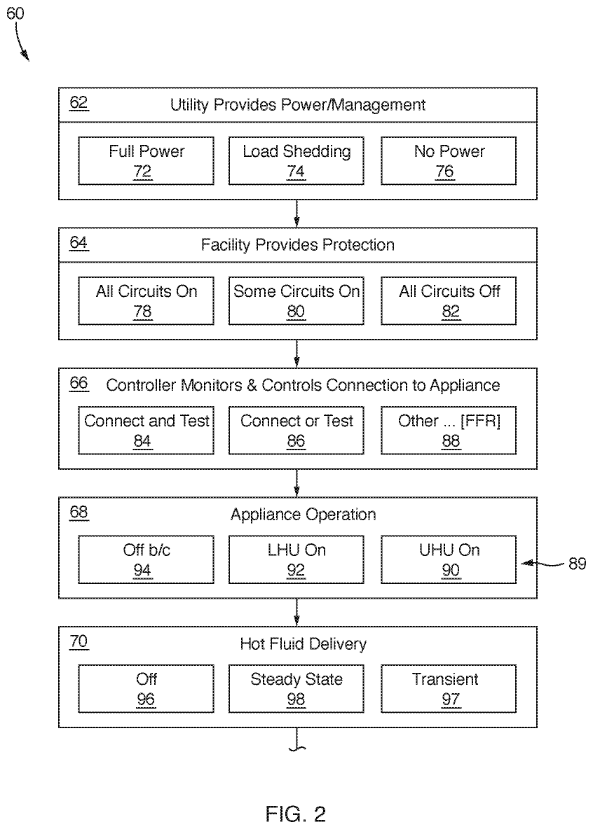

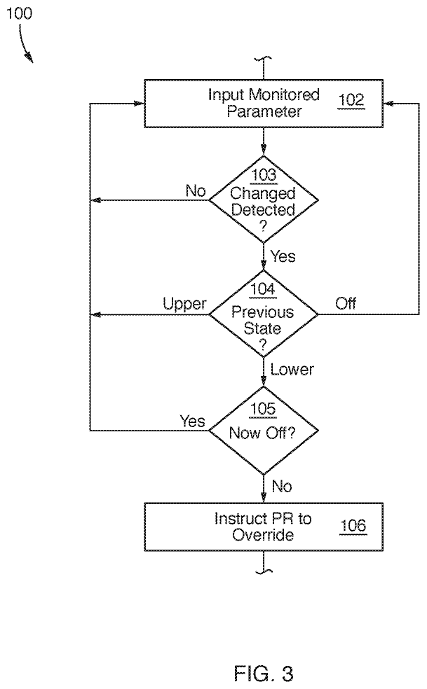

Referring to FIG. 2, with its associated FIGS. 3 through 6, a process 60 or system 60 may include providing 62 by a utility 40 certain power and management functionality. Meanwhile, a facility protects 64 itself by breakers 23 between its power distribution on system and a utility source 24 powering an appliance 14. Likewise, monitoring and control 66 are a responsibility of the controller 12 connected to an appliance 14. Operation 68 of the appliance 14 may be thought of as a system and method 68 for transitioning the appliance 14 between different states 89 of operation. If an electronic or software system is embedded or embodied in a native controller 13, then this may be a sophisticated measurement and control mechanism 13. On the other hand, in certain contemplated embodiments of an appliance 14 to which the controller 12 may apply, the operation of the appliance 14 is controlled entirely within itself. The relationship between the lower thermostat 17 and upper thermostat 19 controls their respective heating units 16, 18. Thus, a controller 12 operates regardless of the source 24 or the appliance 14.

Thermomechanical thermostats 17, 19 each control a mechanical switch that shifts electricity or directs electricity to the lower unit 16 or upper heating unit 18 according to a protocol and connection. For example, in one embodiment, the thermostat 19 may operate a double throw relay, while the lower thermostat 17 only needs a single throw type. In such an embodiment, the upper thermostat 19 may, based on temperature that it senses, direct all the power through a first pole to the thermostat 17 corresponding to the heating element 16. A second, opposite, pole associated with the upper thermostat 19 may switch the power to itself whenever the upper thermostat 19 detects that a lower bound of the dead band of its control set point exceeded downward.

This is but one embodiment of an appliance 14. By whatever mechanism, the appliance 14 may be taken as it exists from a manufacturer. Installed at a venue, its user or owner may control it with a controller 12 in order to better optimize and trade off the desire of a user conservation. This may be by lower power rates, lower power usage, off peak use, or the like. It may be traded against or overridden the desirability of not permitting the outlet 48b of the appliance 14 to ever put out liquid at too low (unacceptable) temperature. Ultimately, hot fluid delivery 70 is the functional purpose of an appliance 14. Power conservation is a desirable objective, but a failure of delivery 70 of hot fluid from the tank 11 is highly undesirable.

Thus, providing 62 power and power management, a system 10, 12 in accordance with the invention and a process 60 may operate in a condition of full power 72, load shedding condition 74 (by request, demand, calendar, or the like), or a condition of no power 76, which would be off 76. Meanwhile, the facility, or venue for the appliance 14 and controller 12 will provide protection, typically in a breaker 23 or breaker box 23, connected back to a utility 40 or other electrical grid. To provide protection 64, the breaker system 23 may have one of three states 89 or conditions 78, 80, 82. It may have an “all on” condition 78, in which all circuits are on. In a condition 80, some circuits are on. In a condition 82, all circuits are off. Again, circuits being turned off may occur because a breaker 23 was overloaded and has switched off. Likewise, certain circuits may be disabled intentionally, or circuits may simply be idle. Regardless, providing protection 64 is the responsibility of the breaker system 23.

The controller 12 receives power through a line 28 (single line represents a circuit). The controller 12 monitors and controls 66 connections between the line 28 and the appliance 14. Thus, the controller 12 simply accepts the power coming from the utility source 24 in whatever condition it is, and determines how and when to deliver power to the appliance 14. Typically, in accordance with the diagram of FIG. 1, any one of three circuits may monitor. Control 66 includes a condition 84 or state of connect and test 84. This occurs in either of the circuits 26b, 26c with the power monitor 25 monitoring the electrical parameter to be measured and recorded.

A connect or test condition 86 is the situation wherein the RMC 26a is used as both a source of power and a monitor of the electrical parameter, reflecting a state 89 of the appliance 14, to be measured. Other mechanisms or conditions 88 may also exist. For example, the RMC 26a does not require the power monitor 25. The CD unit 25b does require the power monitor. Likewise, the TD unit 26c, or TD circuit 26c, does require the power monitor 25 to detect the electrical parameter. However, the PR 25 is capable of detecting any of several commonly measurable parameters such as voltage, current, resistance, frequency, power, or the like being passed through the lines 28 passing through the PM 25 in the line 28 or circuit 28 to the controller 12 and the appliance 14.

If frequency drifts, the PM 25 may instruct the processor 21 to shut off the PR 20. Likewise, if voltage wanes or some other anomaly occurs from the utility source 24, the power monitor 25 may detect that anomaly and instruct the processor 21 to shut down the power to the line 22. In particular, a fast frequency response (FFR) may militate for the power monitor 25 to instruct the processor 25 to open the switch 32 (instruct the power relay 20 to open the switch 32).

The operation 68 of the appliance 14 has three distinct states 89. The three states 89 are upper heating unit 18 on 90, lower heating unit 16 on 92, and off 94. The off condition 94 may exist for any reasons mentioned hereandabove. A utility source 24 may be shut off by a breaker 23, another switch, or the utility 40 itself. Similarly, the off condition 94 may also exist because the PR 20 has opened the switch 32. Regardless of how it arrives at that condition 94, the appliance 14 is in the off condition 94.

On the other hand, the differentiation and control of the upper on condition 90 and the lower on condition 92 depend on the protocol built into the native controller 13 or thermostat 17, 19 in the appliance 14. Electronically, a native controller 13 may be programmed in any suitable manner of no interest to the controller 12. However, the two on conditions 90, 92 affect the controller 12. If the operation 68 is in an on condition 90, then the PR 20 needs to provide power to the appliance 14. If power upstream from the controller 12 is off, nothing can be done by it. Otherwise, PR 20 should still close the switch 32.

One reason for this is that an upper on condition 90 indicates that, for whatever reason, the lower heating unit 16 is incapable of keeping up with the demand for water at temperature leaving the outlet 48b. Water through the inlet 48a (along with thermal inertia if it has been off) is cooling the tank 11 and its contents faster than the lower heating unit 16 can keep up. The upper heat on condition 90 exists because the upper thermostat 19 has triggered and turned on the upper heating unit 18. This occurs in response to the upper thermostat 19 sensing a temperature that below its set point, which is already lower than the set point of the lower thermostat 17. The controller 12 needs to interfere to assure sufficiently hot water at the outlet 48b.

As described hereinabove, each of the heating units 16, 18 heats all the water or other liquid above it when activated. Accordingly, only one of the heating units 16, 18 ever needs to be on at a given time. The control mechanism directing power to the lower heating element 16 or upper heating element 18 may be done in any suitable manner. However, a double throw switch operated by the upper thermostat 19. So long as it is not triggered, itself, it directs power to the lower thermostat 17. Thus, directing power between the upper and lower units 16, 18. The lower thermostat 17 needs only a single throw switch (off/on) to turn the lower heating element 16 on or off according to the set point for temperature sensed by the lower thermostat 17.

Delivery 70 of hot fluid from the outlet 48b, may also have one of three states 96, 97, 98 or conditions 96, 97, 98. It may be off 96, due to no demand, transient 97, or in a steady state 98, meaning the lower heating unit 16 is keeping up with demand, switching on 92 only by its own thermostat 17. The upper thermostat 19 need never trigger unless its temperature descends below the dead band of its set point. A transient condition 97 will exist when the upper heating unit 18 is operating in a somewhat urgent mode 97, heating a smaller volume of liquid in the tank 11, above it. This transient condition arrives for either two reasons. The heating element 18 may or may not be able to keep up with demand. Temperatures actuating the thermostat 19 may never get above its dead band. Also, any heating by the upper heating unit 18 is temporary. Once the draw of water or other liquid from the outlet 48b has slowed sufficiently or has come to a stop, the upper heating unit 18 will heat all the liquid thereabove, which will then exceed the top limit of the dead band of the set point for upper thermostat 19, which will then direct power back to the lower thermostat 17 and heating unit 16.

Referring to FIG. 3, while continuing to refer generally to FIGS. 1 through 6, a process 100 for determining the state 89 of the appliance 14 may include inputting 102 a monitored parameter to the processor 21. Typical parameters may be anything measurable electrically as known in the art. For example, voltage current, resistance, power, frequency, and the like may measure either directly or calculated from another directly measurable parameter.

Logic may be illustrated in several different models, this one using steps and decisions is one. This schematic is not controlling of all the ways that the process may be done. The point is that a test 103 may determine whether a change has been detected in whatever parameter is being measured. If no significant change outside of possible noise is detected, then continued input 102 of the monitor parameter may continue until the test 103 reveals a change. A change detected typically means that an event has occurred within the appliance 14 changing its state 89. Again, the state 89 transitions from off 94 to lower heating unit on 92.

The transition to upper heating on 90 may typically change from a lower heating unit on condition 92. The transition to off 94 is most frequently from the lower heating unit on condition 92. However, the transition from the upper heating unit on 90 may go directly to off 94. Alternatively, it may go directly to the on condition 92. The controller 66 need not be aware of the transitions. However, transitions may cause spikes in the value of the parameter measured, long term changes in the value itself and may show increasing and decreasing values as the measured parameter steadies out. Moreover, different heating units 16, 18 may even have different resistances, even if only a small fraction of and Ohm.

If a change is detected 103, an algorithm or program in the processor 21 may determine 104 the previous state 89, 104 as described below. The test 104 for the previous state 89 results in ongoing inputting 102 if the previous condition was an upper heating unit on 90. Similarly, if the previous condition was off 94, inputting 102 may continue. Parameters become available through whichever of the various types of sensing units 26a, 26b, 26c is the EPMU 26. Because a limited number of transition paths typically exist between the operational conditions 90, 92, 94, a change from a known previous state 89 may help infer the current state 89. For example, if the previous state 89 was off 94, then the new state 89 may typically be lower heat on 92. However, if the previous state 89 was lower heat on 92, then the current state 89 should be either off 94 or upper heat on 90. If off 94, an open circuit in the heater has an effectively infinite resistance, easily detectable. If resistance is similar to that of a previous state, then the heating unit 16, 18 has been changed.

If the previous state 89 was lower heat, then if the test 105 indicates that the lower heat is now off 94, then inputting 102 continues. However, if the previous state 89 was lower heat on 92, and the state 89 has changed but is not off 94, then the lower heating unit 16 is not keeping up with demand. Thus, the change in state 89 has been a return of control to the upper thermostat 19 and the engagement of the upper heating unit 18. At this point, the processor instructing 106 the PR 20 to override any existing instruction to conserve energy is appropriate, maybe even necessary, in order to avoid a cold water discharge through the outlet 48b.

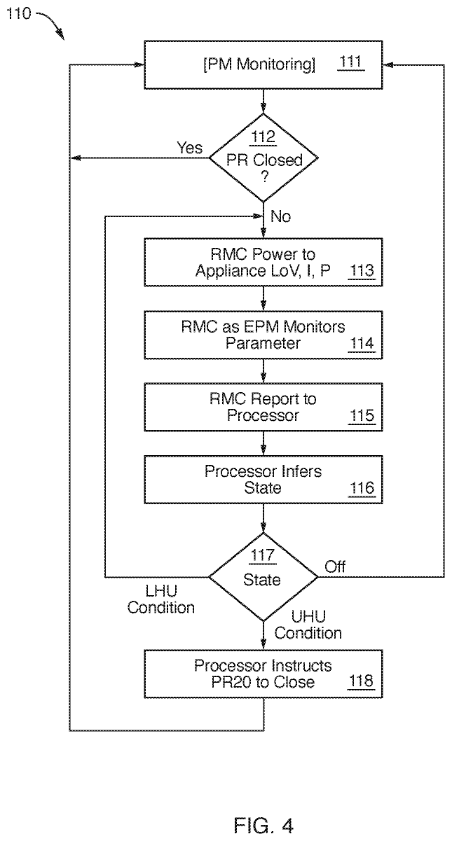

Referring to FIG. 4, a process 110 for the RMC 26a to act as an EPMU 26 and power supply is illustrated. In this embodiment, monitoring 111 by the option power monitor 25 is unnecessary for this purpose. It may still be useful for others. Such monitoring 111 still has other valuable uses, such as monitoring line frequency in the line 28, and the like. However, as a control for the power relay 20 based on the state 89 of the appliance 14, the power monitor 25 is unnecessary. In fact, communication 34 with the utility 40 is likewise unnecessary in such an embodiment, but has other valuable uses like communicating requests for load-shedding.

In this illustrated example, the RMC 26a is reporting to, or being monitored by, the processor 21. Accordingly, a test 112 may determine whether the PR 20 is closed. If so, then monitoring 111 may simply continue. However, if the PR 112 is not closed 112, then the RMC 26a sends power enough to the appliance to sense the measured parameters it will sense as an EPMU 26.

With the PR 20 open (on pole 30), the process 110 moves on to powering 113 by the RMC 26a the circuit through the normally off pole 30, switch 32, line 22, and appliance 14. Any suitable electrical parameters may be monitored 114. Nevertheless, the power provided 113 by the RMC 26a is much lower in voltage (e.g., 3 to 20, typically 5 volts), much lower in current (e.g., milliamps), much lower in total power, and will not damage substantially the contacts on the switch 32 of the power relay 20. Power operations may use about 5 to 40 amps, usually 10 to 30). Corresponding voltages may be 110 to 220.

Power relays 20 suffer most of their damage from two causes. The first is arc damage caused by opening and closing contacts between the switch 32 and the poles 28, 30. Every time a contact is opened or closed, it draws an arc, if carrying operational (heating) power. At the voltages and currents across the PR 20, drawing an arc is a given. Contact materials and so forth may help delay failure, but it will happen. The other principle failure mode is mechanical failure due to parts moving, stressing, and failing mechanically.

In the illustrated example, power for measuring parameters, as provided by the RMC 26a, is so much lower in voltage, current, and overall power than those parameters provided by the utility source 24 through the power monitor 25 and line 28, that operation of the RMC 26a provides substantially no increase in “wear” or damage. Meanwhile, because the PM 25 may be available when using the RMC 26a circuit for measurement, continual monitoring is possible. That is, with an RMC 26a available, the PM 25 may still provide monitoring of the lines 28, 22, and the apparatus 14 when the RMC 26a is inactive. Power is being delivered by the power relay 20 to the apparatus 14 and the PM 20 can monitor parameters.

On the other hand, the RMC 26a may operate as a measurement device 26 taking measurements whenever no operational power goes to the appliance 14. When the RMC 26a provides “power off monitoring,” it saves many cycles on the PR 20, and prevents arc damage by eliminating the need to operate the PR 20 unnecessarily. That is, for example, the power relay 20 may remain in the normally closed position 28 while operational, and simply open to the normally open pole 30 and the resistance measurement circuit 26 when a desire or instruction is received from the processor 21 to shut power off for power conservation. The EPMU 26 and controller 12 provide an override by the PR 20 of those instruction when warranted. Thus, mechanical wear and aging, as well as contact arc damage are reduced by use of an RMC 26a.

The RMC 26a monitors 114 the electrical parameter desired to be measured when the acting as an EPMU 26, even when the open condition of the PR 20 renders the PM 25 otherwise unavailable for measurements. That is, the PM 25 is disconnected from the line 22 and appliance 14 anytime the PR 20 moves to the normally open pole 30. With the RMC 26a available as an EPMU 26, no need exists for putting the PR 20 into the normally closed position 28 or pole 28 just for monitoring during energy conservation. This reduces by orders of magnitude the number of times contacts in the PR 20 must connect and disconnect, and therefore greatly extends its life. Meanwhile, the capability of the controller 12 and its PR 20 to override a power conservation condition is virtually unlimited.

The monitoring 114 by the RMC 26a (and any EPMU 26) results in reporting 115, by the RMC 26a data to the processor 21. Data include values of parameters at any suitable sampling speed. All may be input 115 (reported 115) to the processor 21.

The processor 21 infers 116 as discussed hereinabove the state 89 of the appliance 14 in operation 68, based on the value or values (a series of measurements over a period of time of the parameter of interest) provided to the processor 21 by any EPMU 26. By “reporting” 115 regularly, the EPMU 26 provides data for an inference, 116 by the processor 21, of the current state 89. This may be done by observing events affecting measurements of parameters themselves. It may be done by tracking changes in the state 89. Measurements of parameters in the current state 89 to the. Measurements of those parameters may be compared with those of different state 89. Alternatively, the change in state 89 may be inferred by the fact that any changes occurred, and by a knowledge of a previous data histories of states 89 stored by the processor 21 for purposes of programmed calculations.

Thus, as illustrated in FIG. 3, a process 100 for inferring 116 a state 89 of the operation 68 of the appliance 14 provides an answer to the question 117 or test 117 of what that state 89 is. If the state 89 is the lower heating unit on 92 (LHU on 92) then the process 110 may return back to the RMC 26a powering 113 and monitoring 114 the electrical parameter of interest. Meanwhile, if the state 89 is off 90 then the process 110 may return back to its beginning with monitoring 111 by the optional PM 25.

However, if the upper heating unit on condition 90 (UHU on 90) exists then the processor 21 instructs 118 the power relay 20 to close, move the switch 32 to the normally closed pole 28. This instruction 118 amounts to an override 118 of any previous instruction that may have opened the switch 32 in the PR 20 in response to a request for power shedding, scheduled and programmed conservation programmed into the processor 21.

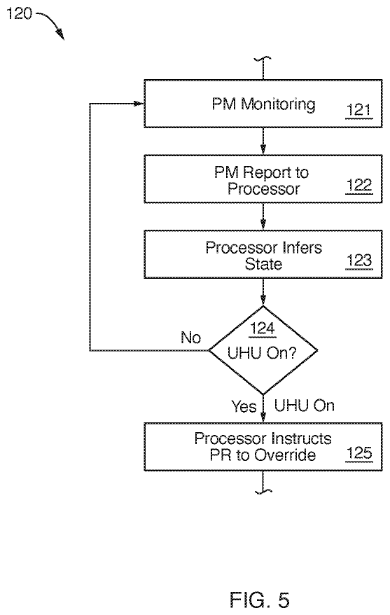

Referring to FIG. 5, monitoring 121 by the PM 25 is not optional in this embodiment, applicable to either of the CD circuit 26b or the TD circuit 26c. Either of those configurations 26b, 26c, runs parallel to the PR 20. The PM 25 may report 122 to the processor 21 the value of any measured parameter in the EPMU 26, operating it, as an EPMU 26. As described with respect with FIG. 4, the processor 21 infers 123 a state 89 of the appliance 14. If the upper heating unit 18 is in the on condition 90, the processor 125 may instruct the power relay 20 to override whatever instructions the processor 21 has provided as far as power conservation. On the other hand, any other state 89 may still support monitoring 121 by the PM 25 with the PR 20 open (off).

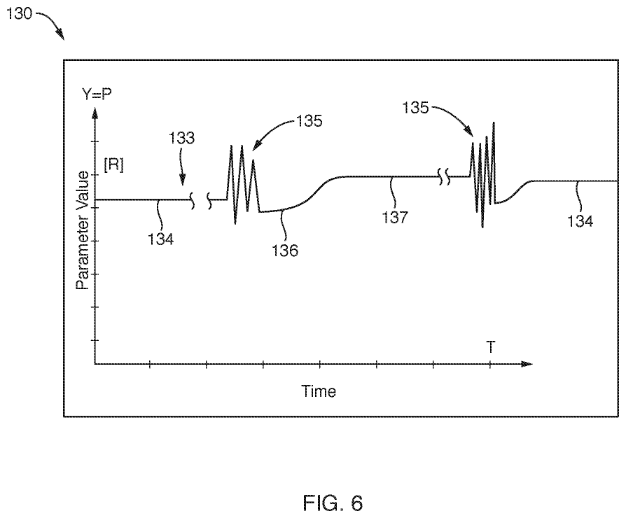

Referring to FIG. 6, while continuing to refer generally to FIGS. 1 through 6, a chart 130 includes an abscissa 131 or x axis 131 representing time 131. Meanwhile, the y axis 132 or ordinate 132 represents a parameter “R” which may be any suitable parameter. In this instance, the letter ‘R’ is used because one parameter measured may often be resistance. Measuring resistance is cheap, easy, and ubiquitous. In the chart, a trace 133 represents the values of 134, 137 of the measured parameter 132. That is, the axis 132 represents a value 132 of the parameter 132.

The trace 133 has several portions, including a first state portion 134 representing a value in one particular state 89. Switching by the PR 20 or either of the thermostats 17, 19, will typically cause a transient condition 135. A transient 135, typically (resistance, voltage, or current) will spike, drop off, or both. This artifact 135 may be captured because the EPMU 26 in accordance with the invention may monitor at substantially any practical periodicity or frequency desired. The trace 133 may be monitored, recorded, and stored by the processor 21 for comparisons later. A transient 135 may often be easily detected, since they typically last for a small fraction of a second to leave data points in the record.

Meanwhile, resistance in each of the heating elements 16, 18 or heating units 16, 18 is simply an electrical phenomenon in materials. Thus, the transient 135 will typically end with a cold rise 136 or rise 136 in resistance as any heating unit 16, 18 begins to warm. This typically lasts for a matter of several seconds, about five to ten, typically. The drop in resistance due to current passing from a hot heating element 16, 18 to the opposite, colder element 18, 16 may provide an artifact 135 lasting several seconds and often easily detected by the EPMU 26 in any of the configurations 26a, 26b, 26c.

Ultimately, the value 132 of the parameter 132 represented on the axis 132 will be reflected in a steady state portion 137 of the trace 133. Comparing the value of the trace 134 to the value of the trace 137 may actually be sufficient to detect which of the elements 16, 18 was previously active and which is presently active. However, the fact that a switching transient 135 exists, and the fact that the rise 136 from the lower resistance to the higher resistance as either element 16, 18 heats up, is not only detectable, but lasts for several seconds, enough to take several measurements by an EPMU 26. It also signals a change.

In reflecting on an apparatus and method in accordance with the invention, a system 10 may be considered to be a controller 12 operating between a utility source 24 and an appliance 14. In other contexts, a system 10 may be considered to be the source 21, controller 12, and appliance 14. Typically, communications over links 36a, 36b, 36c between communication devices 34, 38a, and the like provide services beyond or separate from those provided by or required a controller 12. Accordingly, they may be used, but are not necessary for operation of the controller 12. Similarly, the PM 25 is useful for many purposes, and is unnecessary for certain embodiments of an EPMU 26, as discussed hereinabove. The controller 12 adapts to whatever the condition of the line 28 presents from the utility A/C source 24.

It is acknowledged that the EPMU 26 is not required to monitor and control the power relay 20. That is not the point. The PR 20 operated in accordance with the invention may detect and respond to a threat of a cold water discharge whether the PR 20 or appliance 14 is on or off. A cold water discharge means discharge through the outlet 48b of water at a sufficiently low temperature to be undesirable, uncomfortable, unacceptable, or the like for the user of the appliance 14. In each embodiment, a system 10 or a controller 12 in accordance with the invention provides both detection of, and response to a cold water event (e.g., the heater 18 turning on). One purpose or point is to provide or permit conservation measures but override them when appropriate. A controller 12 in accordance with the invention may prevent or eliminate a cold water discharge by “off” state 94 monitoring, while still taking advantage of any energy conservation mechanisms implemented “electrically upstream.”

Because the EPMU 26, whether implemented in an RMC 26a CD 26b, or a TD 26c need only typically operate at about three to five volts and a trickle of current on the order of milliamps. A classical “555 timer” may be used to measure resistance. A distinct native controller 13 is unnecessary. However, as more devices of all types are connected to electronic controllers, a native controller 13 may be electronic. On the other hand, any functionality or structure that operates as a native controller 13 may simply be built into the thermostats 17, 19 and the switches therein operated to turn current off and on into the heating units 16, 18. Thus, the native controller 13 may be regarded as simply a schematic representation of the fact that an appliance 14 has some mechanism for control which may be electronic, but which may be thermomechanical as described hereinabove.

It is significant that the controller 12 operates regardless of the state 89 of the utility source 24 and the appliance 14. The controller 12 may provide monitoring during any state 89 and a change of that state 89 if conservation processes and connections need to be suspended in order to remediate a cold water event in the appliance 14. Thus, a system 10, and particularly a controller 12 and appliance 14 obtain the maximum benefit of any conservation measures effected by a utility 40 by itself, or by request to the controller 12, while remediating a cold water event. One valuable tool for that is the EPMU 26 and its ability to continually monitor the state 89 of the appliance 14, whether or not operational power (e.g., operating voltage and current) are provided to the appliance 14. A system 12 or controller 12 in accordance with the invention provides a simple, robust, long-lived operation for itself and a controlled appliance 14. Meanwhile, a home owner, for example, or other owner may set the set points for the thermostats 17, 19 with no need to program the controller 12.

This ability to detect the state of a device 14 such as the appliance 14, of which a water heater 14, is a typical example is capable of determining the state 89 in an unpowered condition. It provides important information, historical information, and values of parameters that can be processed in many ways to determine patterns, condition, state 89, and the like. Thus, the controller 12 allows the processor 21 to determine when to connect and disconnect power to the end device 14 in use. The system 12 or controller 12 can respond to some grid events like frequency distortions even without communication to a utility 40. Meanwhile, remote commands may be administered by a utility 40 or communication links 36a, 36b, 36c regardless of the state 89 of the appliance 14. Communication devices 34, 38 may also support downloads of commands, updates to software requests, telemetry data, identification of states 89, and the like. Meanwhile, both incoming lines 28 and outgoing lines 22 may be monitored for classic electrical parameters such as voltage, current, power, frequency, and so forth.

The concept of a double throw relay 20 as the power relay 20 provides an extra pole 30 through which an RMC 26a may operate as an EPMU 26. A single pole relay may also be used with a CD 26b or a TD 26c. The bottom line for overriding the state 89 is detecting when a cold water event has occurred, activating the upper heating unit 18.

Any thermal appliance has a certain amount of electrical “inertia.” It typically does not shut down instantly no matter what the impetus for change. The liquid in a tank 11 of an appliance 14 has a massive thermal inertia that requires minutes and sometimes hours to change. Thus, detecting a cold water event rapidly through the thermostat 17, 19 is comparatively much slower than simply detecting rapidly the state 89. In a system 10 in accordance with the invention, the state 89 can be determined in a fraction of a second and the controller 12 can respond similarly. Processing speed through the processor 21 becomes trivial in the timeline of control. Other mechanisms are up to orders of magnitude less precise in measurement and time of response. Prior art systems typically could only respond with a detection time of about five minutes compared to the controller 12 responding in less than a minute, typically seconds. With stored data in the processor 21 sub-second response times are reasonable. Meanwhile, the lifetime of the controller 12, particularly that of the power relay 20 is extended by orders of magnitude. Typically, cycle-number-based lifetimes of a power relay 20 in a system 12 in accordance with the invention may increase by 2400. Meanwhile, all of these benefits are accomplished with no compromise to the load-shedding capability of a utility 40 on its own, or through a request to the controller 12.

The present invention may be embodied in other specific forms without departing from its fundamental functions or essential characteristics. The described embodiments are to be considered in all respects only as illustrative, and not restrictive. All changes which come within the meaning and range of equivalency of the illustrative embodiments are to be embraced within their scope.

Wherefore, we claim:

1. An apparatus comprising:
a relay system operably connected to selectively control availability of operational power and measurement power to a water heater, characterized by a plurality of states;
an electric parameter measurement unit (EPMU) operably connected to detect a state of the plurality of states by measuring an electrical parameter corresponding to power delivered to the water heater;
a processor (logic device) operably connected to the EPMU and the relay to be effective to control operation of the relay, based on a signal from the EPMU reflecting the state of the water heater.

2. The apparatus of claim 1, wherein:
the plurality of states includes an “off” state, a “lower on” state, and an “upper on” state; and
the electrical parameter is selected from a current, voltage, power, capacitance, resistance and a combination of at least two thereof.

3. The apparatus of claim 1 wherein:
the apparatus is configured to be capable of measuring the electric parameter when the water heater is in an off state;
the relay is operably connected to one of a capacitor circuit, a triac circuit, and a resistance measurement circuit.

4. The apparatus of claim 1, wherein the water heater comprises a self-control system including the upper thermostat and lower thermostat, operable to selectively direct power to an upper heating element and a lower heating element by mechanically responding to temperature in the water heater.

5. The apparatus of claim 1, wherein the state is detected by at least one of a PMS and an RMC measuring an electrical parameter reflecting the state of the water heater.

6. The apparatus of claim 5, wherein detection is accomplished by detecting a singularity or discontinuity in the time derivative of the electrical parameter.

7. The apparatus of claim 1, wherein the relay is a double throw relay.

8. The apparatus of claim 1, wherein the relay is connected to an operating pole in each of a first throw position and second throw position, whether connected to power or not.

9. The apparatus of claim 1, comprising a PMS capable of monitoring power from a public utility grid and measuring the electric parameter corresponding to the water heater.

10. The apparatus of claim 1, wherein power to the water heater is provided from the RMC, PMS, public power grid, or a combination of at least two thereof.

11. The apparatus of claim 1, wherein the relay controls both electrical connectivity of the water heater to a source of power and to a device for measurement of parameters reflecting a state of the water heater.

12. The apparatus of claim 1, wherein the apparatus includes connections between components thereof admitting only two options for power to the water heater comprising a trickle power incapable of operating the water heater, and operating power capable of heating water in the water heater.

13. The apparatus of claim 1, wherein power at any time is sent into the water heater substantially directly and exclusively from only one of 1) the PMS, and 2) the RMC.

14. The apparatus of claim 1, wherein the relay is operably connected to provide two modes of operation including a first, operational power delivery mode, and a second, test power delivery, mode.

15. The apparatus of claim 14, wherein the relay is configured to provide the two modes each individually and exclusively at any given time.

16. The apparatus of claim 14, wherein the relay is configured to provide the two modes simultaneously.

17. The apparatus of claim 14, wherein:
the relay is configured to provide two modes of operation, including 1) a power mode providing operational power and test power simultaneously to the water heater, 2) a test mode providing test power only to the water heater.

18. A method comprising:
providing a controller, operable to connect to a water heater, and comprising a relay system, resistance measuring circuit (RMC), power monitoring system (PMS), and processor, operably interconnected to selectively control availability of power directed to a water heater characterized by a plurality of states;
switching, by the relay, operational power, capable of heating water in the water heater;
instructing, by the processor, the relay to disconnect the operational power to the water heater;
providing testing power to the water heater by at least one of the relay system, the PMS, and the RMC;
detecting, by the PMS a parameter reflecting the testing power and a response of the water heater to the testing power;
determining, by the processor, a state of the water heater, based on a value of the parameter; and
instructing the relay, by at least one of the PMS, RMC, and processor, to provide operational power to the water heater.

19. The method of claim 18, comprising switching, by the relay between an operational power mode passing operational power to the water heater and a testing power mode passing testing power, orders of magnitude less than the operational power through the relay to the water heater.

20. The method of claim 18, comprising providing the operational power from the PMS, and the testing power from the RMC.
